(19) United States
(12) Patent Application Publication
(10) Pub. No.: US 2024/0298422 A1
(43) Pub. Date: Sep. 5, 2024

(54) COOLING RAIL REMOVAL TOOL

(71) Applicant: INTERNATIONAL BUSINESS MACHINES CORPORATION, ARMONK, NY (US)

(72) Inventors: Nathan Lee Dunfee, Rochester, MN (US); Christopher M. Marroquin, Rochester, MN (US); Brandon R. Christenson, Kasson, MN (US); Arthur J. Higby, Cottekill, NY (US)

(21) Appl. No.: 18/177,499

(22) Filed: Mar. 2, 2023

(51) Int. Cl. H05K 7/20

(52) U.S. Cl. CPC H05K 7/20254

(57) ABSTRACT

A computer hardware assemblage includes a planar, a cooling rail, and a tool. The planar includes a board with a side and an electronic component connected to the board. The cooling rail is connected to the planar and includes a side that faces the side of the board, another side that is opposite to the other side, and a cooling feature that is thermally connected to the electronic component. The tool is connected to the cooling rail such that a side of the tool faces the other side of the cooling rail, and the tool is in direct contact with the planar.

### BACKGROUND

The present disclosure relates to computing systems, and more specifically, to tools for disassembling computer hardware.

Many computing systems include circuit boards with electronic components that generate heat during operation. In order to better cool these components, various cooling structures can be thermally connected thereto. Oftentimes, a thermal interface material (TIM) is sandwiched between the components and their respective cooling structures. While the TIM aids in heat transfer, it can also stick a cooling structure to a component. Thereby, it can be difficult to remove the cooling structure from the component if either of them needs to be repaired or replaced.

### SUMMARY

According to one embodiment of the present disclosure, a computer hardware assemblage includes a planar, a cooling rail, and a tool. The planar includes a board with a side and an electronic component connected to the board. The cooling rail is connected to the planar and includes a side that faces the side of the board, another side that is opposite to the other side, and a cooling feature that is thermally connected to the electronic component. The tool is connected to the cooling rail such that a side of the tool faces the other side of the cooling rail, and the tool is in direct contact with the planar.

According to another embodiment of the present disclosure, a computer hardware assembly includes a cooling rail, a tool, and fasteners. The cooling rail includes a body with fastening features and a cooling feature that is configured to be thermally connected to an electronic component. The tool includes fastening features and standoffs. The fasteners extend between the fastening features to connect the tool to the cooling rail.

According to another embodiment of the present disclosure, a method of working on a computer hardware assembly includes applying a layer of thermal interface material to an electronic component of a planar, connecting fasteners between the planar and the cooling rail, and disconnecting the fasteners between the planar and the cooling rail. The method also includes positioning a tool over the cooling rail and in direct contact with the planar, connecting fasteners between the tool and the cooling rail, and operating, further, the fasteners to draw the cooling rail towards the tool and away from the planar.

### BRIEF DESCRIPTION OF THE DRAWINGS

FIG. 1A is a perspective view of a computer hardware assembly (CHA), in accordance with an embodiment of the present disclosure.

FIG. 1B is an exploded perspective view of the CHA, in accordance with an embodiment of the present disclosure.

FIG. 2 is a perspective view of the CHA with a tool, in accordance with an embodiment of the present disclosure.

FIG. 3A is a top perspective view of the tool, in accordance with an embodiment of the present disclosure.

FIG. 3B is a top view of a computer hardware assemblage (CHG) including the CHA and the tool, in accordance with an embodiment of the present disclosure.

FIG. 3C is a side view of the CHG, in accordance with an embodiment of the present disclosure.

FIG. 4A is a bottom perspective view of the tool, in accordance with an embodiment of the present disclosure.

FIG. 4B is a top view of the planar, in accordance with an embodiment of the present disclosure.

FIG. 5 is a flowchart of a method of working on the CHA, in accordance with an embodiment of the present disclosure.

### DETAILED DESCRIPTION

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship.

The following definitions and abbreviations are to be used for the interpretation of the claims and the specification. As used herein, the terms “comprises,” “comprising,” “includes,” “including,” “has,” “having,” “contains,” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus. In addition, any numerical ranges included herein are inclusive of their boundaries unless explicitly stated otherwise.

For purposes of the description hereinafter, the terms “upper,” “lower,” “right,” “left,” “vertical,” “horizontal,” “top,” “bottom,” and derivatives thereof shall relate to the described structures and methods, as oriented in the drawing Figures. The terms “overlying,” “atop,” “on top,” “positioned on,” or “positioned atop” mean that a first element, such as a first structure, is present on a second element, such as a second structure, wherein intervening elements such as an interface structure can be present between the first element and the second element.

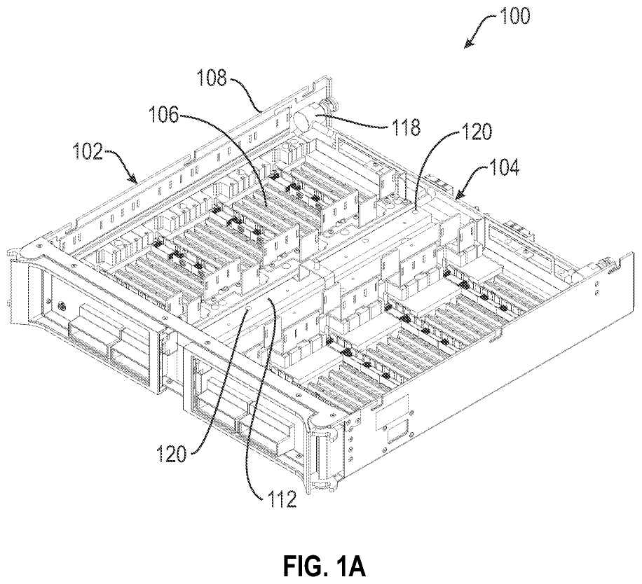

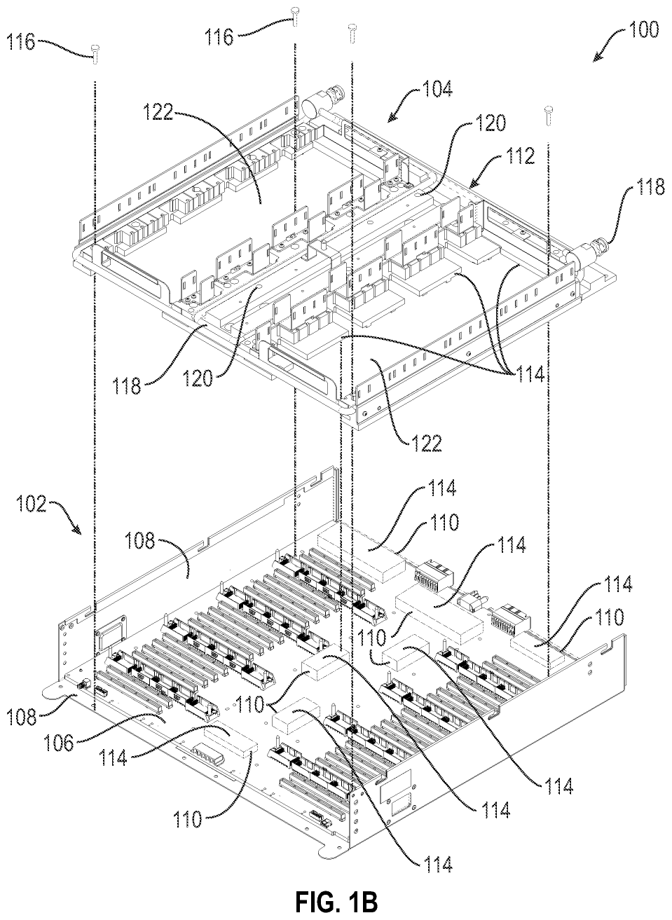

FIG. 1A is a perspective view of computer hardware assembly (CHA) 100. FIG. 1B is an exploded perspective view of CHA 100. FIGS. 1A and 1B will now be discussed in conjunction with one another.

In the illustrated embodiment, CHA 100 comprises planar 102 and cooling rail 104. Planar 102 comprises board 106 and chassis 108. Board 106 is a printed circuit board (PCB) that is structurally supported by chassis 108, which comprises a metal material. Board 106 includes electronic components 110 mounted to its top side. During operation CHA 100, some or all of electronic components 110 can produce heat. Thereby, the bottom side of cooling rail 104 is in contact with the top side of board 106. More specifically, body 112 of cooling rail 104, which is comprised of a heat conducting material (e.g., a metal material), is thermally connected to electronic components 110. This connection can be ensured by adding a layer of thermal interface material (TIM) 114 (e.g., Bergquist® GF3500S) between planar 102 and cooling rail 104 to bridge any gaps that may be present between electronic components 110 and body 112. In some embodiments, TIM 114 is a two-component material, which is mixed prior to being applied to electronic components 110. Then planar 102 and cooling rail 104 are connected (e.g., using fasteners 116), and TIM 114 sets a short time later.

In the illustrated embodiment, cooling rail 104 further comprises fluid duct 118 which is a cooling feature that extends around and is thermally connected to body 112. Fluid duct 118 is configured to provide a route for a heat transfer fluid (e.g., liquid water) to circulate in a closed loop in a heat transfer system (not shown), which draws heat from electronic components 110 via body 112. In other embodiments, cooling rail 104 is a heatsink (e.g., with fins), a heat spreader, or other heat transfer device. Body 112 further includes a plurality of threaded blind holes 120 on the top side which function as fastening features and two large apertures 122 through body 112 that correspond to areas of board 106 that do not need extra cooling and/or need clearance for attachment of other components (not shown).

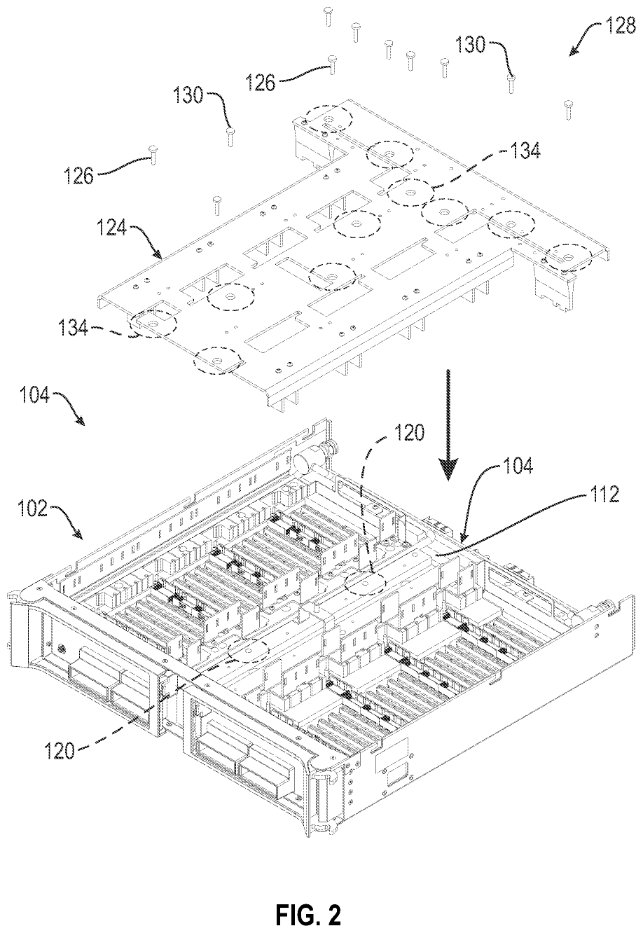

FIG. 2 is an exploded perspective view of CHA 100 with tool 124. Tool 124 can be connected to cooling rail 104 using a plurality of fasteners 126. This combination of planar 102, cooling rail 104, and tool 124 is computer hardware assemblage (CHG) 128.

While TIM 114 (shown in FIG. 1B) thermally connects planar 102 and cooling rail 104, TIM 114 also somewhat structurally connects planar 102 and cooling rail 104. While TIM 114 may not be an adhesive, its tight fit to electronic components 110 (shown in FIG. 1B) and body 112 can have a suction-cup effect that makes separating planar 102 and cooling rail 104 more difficult. Simply pulling up on cooling rail 104 to separate planar 102 and cooling rail 104 can cause bending of board 106, which can lead to permanent damage of electronic components 110 (and/or the electrical connections thereto). While a prying device could be slid in between planar 102 and cooling rail 104 to separate them, such a device can also permanently damage electronic components 110 (and/or the electrical connections thereto).

Thus, the bottom side of tool 124 can be positioned over the top side of cooling rail 104 (i.e., the side opposite of planar 102). In the illustrated embodiment, fasteners 126 are bolts with threaded portions that are positioned through tool 124 and into threaded blind holes 120. Fasteners 126 are then turned to engage the threads in threaded blind holes 120. Once heads 130 contact the top side of tool 124, further turning of fasteners 126 decreases the distance between cooling rail 104 and tool 124, which increases the distance between planar 102 and cooling rail 104. Once cooling rail 104 is pulled far enough off of planar 102 to break the suction seal from TIM 114, cooling rail 104 and tool 124 can be lifted off of planar 102 without damaging planar 102. Because threaded blind holes 120 only extend, for example, one-third of the way through body 112, there is no way for fasteners 126 to contact planar 102 when cooling rail 104 is separated from planar 102.

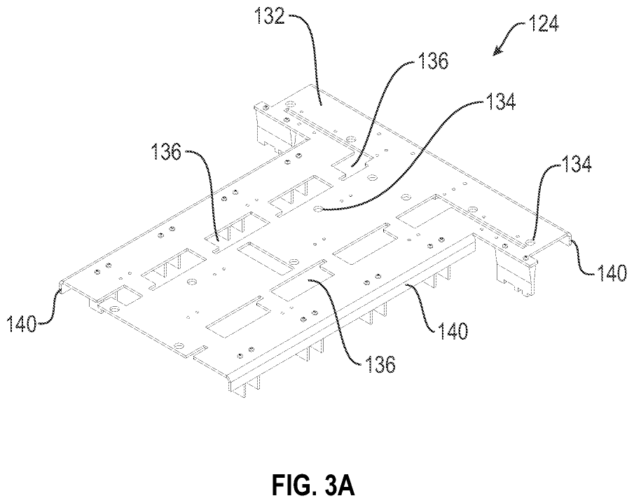

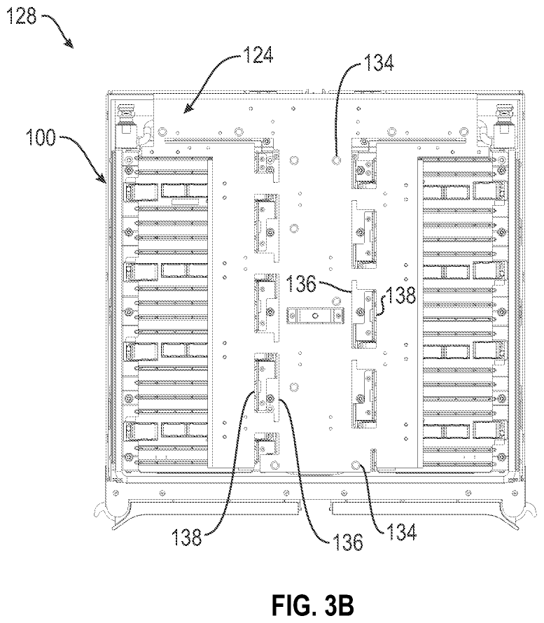

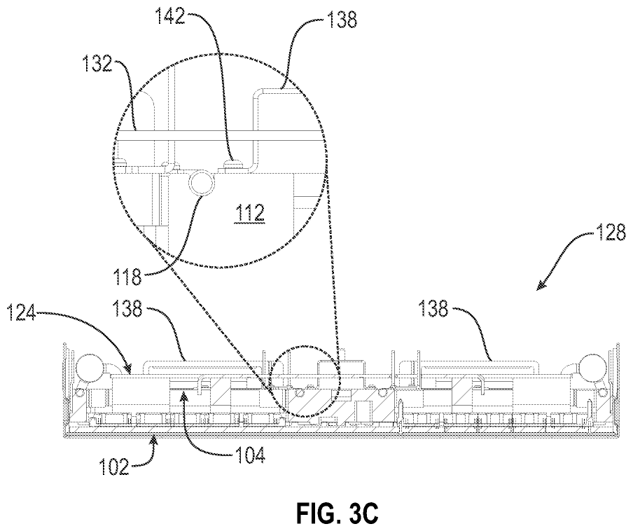

FIG. 3A is a top perspective view of tool 124. FIG. 3B is a top view of CHG 128. FIG. 3C is a side view of CHG 128. FIGS. 3A-3C will now be discussed in conjunction with one another.

In the illustrated embodiment, tool 124 comprises plate 132 which can be a sheet metal component with a plurality of through holes 134 and a plurality of apertures 136 through plate 132. Furthermore, plate 132 includes flanges 140 that stiffen tool 124 such that, in some embodiments, tool 124 is more rigid than planar 102 and/or cooling rail 104.

Through holes 134 are clearance holes through which fasteners 126 (shown in FIG. 2) can pass. Apertures 136 allow for brackets 138 of cooling rail 104 to pass through tool 124, which allows tool 124 to be positioned closer to cooling rail 104 than if tool 124 had to provide clearance for brackets 138. In the illustrated embodiment, plate 132 is positioned beneath the tops of brackets 138 but above bracket fasteners 142. Brackets 138 also assist in locating tool 124 with respect to cooling rail 104 as well as planar 102.

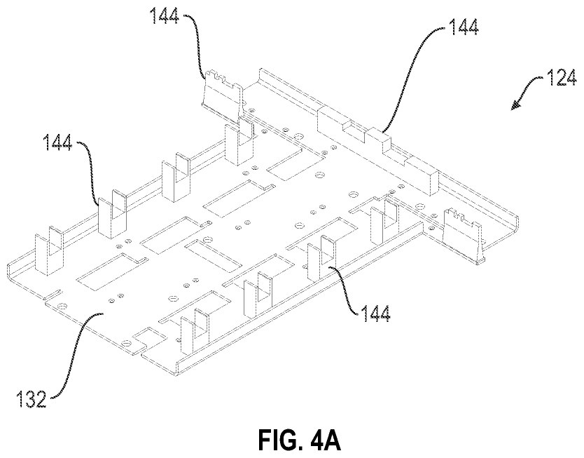

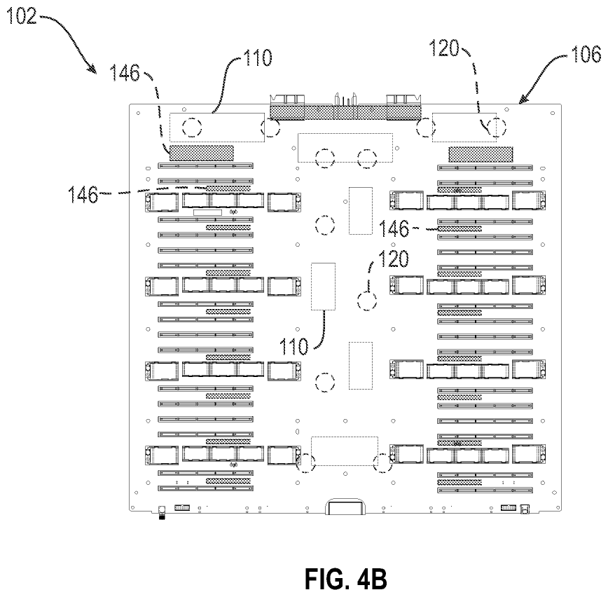

FIG. 4A is a bottom perspective view of tool 124. FIG. 4B is a top view of planar 102. FIGS. 4A and 4B will now be discussed in conjunction with one another.

In the illustrated embodiment, tool 124 comprises a plurality of standoffs 144 that extend from the bottom of plate 132. Standoffs 144 are configured to pass through apertures 122 (shown in FIG. 1B) and contact various locations 146 (shown by gray rectangles) on board 106. This prevents board 106 from being drawn toward tool 124 as cooling rail 104 (shown in FIG. 2) is pulled toward tool 124. In some embodiments, standoffs 144 can be made from a non-scratching material, such as a polymer material to minimize the chance of standoffs 144 damaging board 106 (e.g., marring electrical leads) in a significant manner when standoffs 144 contact board 106. In addition, the ends of standoffs 144 can be contoured (e.g., notched) to match the shape of board 106 and/or to avoid contacting a particular area on board 106 (e.g., a location that includes an electronic component 110). Standoffs 144 can be attached to plate 132, for example, by screws, heat staking, pins and adhesive, and/or by being overmolded.

The positioning of standoffs 144 can be related to the positions of electronic components 110. It can be beneficial to position standoffs 144 and threaded blind holes 120 (shown by phantom circles) as close together as possible. That way, the upward forces on cooling rail 104 from fasteners 126 (shown in FIG. 2) and the downward forces on board 106 from standoffs 144 are less likely to create large bending moments that could damage board 106 and/or cooling rail 104. In some embodiments, since threaded blind holes 120 do not pass all the way through cooling rail 106, threaded blind holes 120 are positioned over electronic components 110.

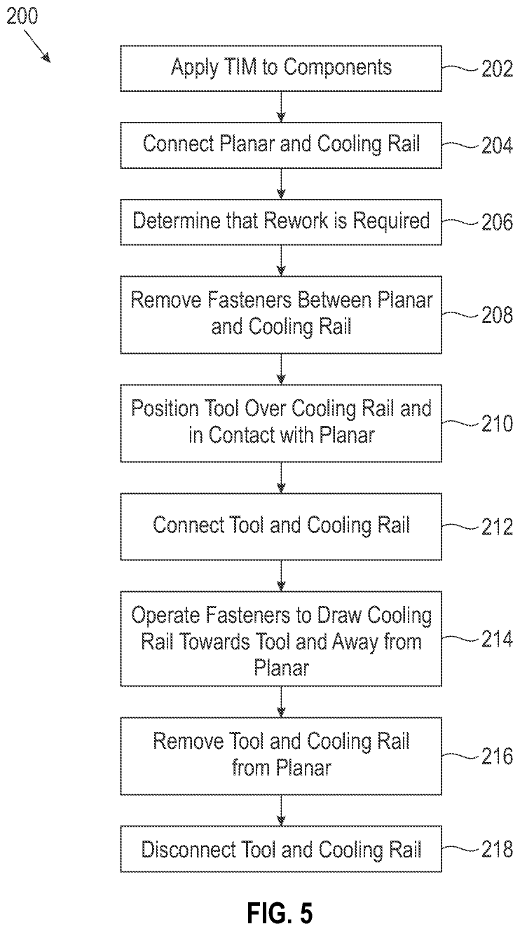

FIG. 5 is a flowchart of method 200 of working on CHA 100. The discussion of FIG. 5 will include references to components shown in FIGS. 1-4B.

In the illustrated embodiment, method 200 begins at operation 202 wherein TIM 114 is applied to planar 102 (specifically to electronic components 110). At operation 204, planar 102 and cooling rail 104 are placed in contact with one another and connected with fasteners 116. At operation 206, it is determined (e.g., by an operator) that rework is required on planar 102 and/or cooling rail 104. At operation 208, fasteners 116 are removed, and at operation 210, tool 124 is positioned over cooling rail 104 and in contact with planar 102 such that standoffs 144 extend through apertures 122 and brackets 138 extend through apertures 136.

In the illustrated embodiment, at operation 212, tool 124 is connected to cooling rail 104 using fasteners 126. Operation 212 can include passing fasteners 126 through through holes 134 and threading fasteners 126 into threaded blind holes 120. At operation 214, fasteners 126 are operated to draw cooling rail 104 towards tool 124 and away from planar 102. Operation 214 can include turning each of the fasteners, for example, ¼ to ½ turn at a time in a star pattern (i.e., moving across tool 124 to tighten opposing fasteners 126 alternately). Thereby, cooling rail 104 can be lifted evenly while minimizing bending of board 106.

Once cooling rail 104 has been raised enough to break the suction seal with planar 102, tool 124 and cooling rail 104 is removed from the vicinity of planar 102 at operation 216. At operation 218, tool 124 can be disconnected from cooling rail 104 by removing fasteners 126.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer hardware assemblage comprising:
a planar comprising:
a board with a first side; and
an electronic component connected to the board;
a cooling rail connected to the planar, the cooling rail comprising:
a second side of the cooling rail that faces the first side;
a third side of the cooling rail that is opposite from the second side; and
a cooling feature that is thermally connected to the electronic component; and
a tool connected to the cooling rail such that a fourth side of the tool faces the third side, wherein the tool is in direct contact with the planar.

2. The computer hardware assemblage of claim 1, further comprising a layer of thermal interface material positioned between the electronic component and the cooling feature.

3. The computer hardware assemblage of claim 1, wherein the tool is connected to the cooling rail by a plurality of fasteners that are configured to increase a distance between the first side and the second side when engaged.

4. The computer hardware assemblage of claim 3, wherein:
each of the plurality of fasteners includes a threaded portion; and
the cooling rail includes a plurality of threaded blind holes that corresponds with the plurality of fasteners such that turning one of the plurality of fasteners in a direction engages a corresponding threaded blind hole to increase the distance between the first side and the second side.

5. The computer hardware assemblage of claim 1, wherein the tool includes a plurality of standoffs extending from the fourth side to directly contact the planar.

6. The computer hardware assemblage of claim 1, wherein a portion of the cooling rail extends through an aperture in the tool when the tool is in direct contact with the planar.

7. The computer hardware assemblage of claim 1, wherein the cooling feature is a fluid duct.

8. The computer hardware assemblage of claim 1, wherein the cooling rail is connected to the planar by a plurality of removable fasteners.

9. The computer hardware assemblage of claim 1, wherein the planar further comprises a chassis connected to the board.

10. A computer hardware assembly comprising:
a cooling rail comprising:
a body including a first plurality of fastening features; and
a cooling feature that is configured to be thermally connected to an electronic component;
a tool comprising:
a second plurality of fastening features; and
a plurality of standoffs;
a plurality of fasteners extending between the first and second plurality of fastening features to connect the tool to the cooling rail.

11. The computer hardware assembly of claim 10, wherein the tool further comprises a standoff that extends through an aperture in the cooling rail.

12. The computer hardware assembly of claim 10, wherein the first plurality of fastening features is a plurality of threaded blind holes.

13. The computer hardware assembly of claim 12, wherein the second plurality of fastening features is a plurality of clearance through holes.

14. The computer hardware assembly of claim 13, wherein the second plurality of fastening features are configured to decrease a distance between the tool and the cooling rail when turned in a same direction.

15. The computer hardware assembly of claim 10, further comprising a layer of thermal interface material positioned on the cooling feature where the cooling feature is thermally connected to the electronic component.

16. The computer hardware assembly of claim 10, wherein a portion of the cooling rail extends through an aperture in the tool.

17. The computer hardware assembly of claim 10, wherein the cooling feature is a fluid duct.

18. A method of working on a computer hardware assembly, the method comprising:
applying a layer of thermal interface material to an electronic component of a planar;
connecting a first plurality of fasteners between the planar and the cooling rail;
disconnecting the first plurality of fasteners between the planar and the cooling rail;
positioning a tool over the cooling rail and in direct contact with the planar;
connecting a second plurality of fasteners between the tool and the cooling rail; and
operating, further, the second plurality of fasteners to draw the cooling rail towards the tool and away from the planar.

19. The method of claim 18, wherein:
connecting a second plurality of fasteners between the tool and the cooling rail comprises:
passing a plurality of threaded fasteners through a plurality of clearance through holes in the tool; and
threading the plurality of threaded fasteners into a plurality of threaded blind holes in the cooling rail; and
operating the second plurality of fasteners comprises turning each of the plurality of threaded fasteners in a direction to draw the cooling rail towards the tool.

20. The method of claim 18, wherein positioning the tool further comprises passing a standoff of the tool through an aperture in the cooling rail.
